(19) United States
(12) Patent Application Publication
(10) Pub. No.: US 2006/0156984 A1
(43) Pub. Date: Jul. 20, 2006

(54) Plasma processing apparatus and plasma processing method

(75) Inventors: Toshihisa Nozawa, Hyogo (JP); Kiyotaka Ishibashi, Hyogo (JP); Toshio Nakanishi, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/288,336

(22) Filed: Nov. 29, 2005

Related U.S. Application Data
(63) Continuation-in-part of application No. PCT/JP04/07485, filed on May 31, 2004.

(30) Foreign Application Priority Data
May 29, 2003 (JP) 2003-152808

(51) Int. Cl. C23C 16/00; C23C 14/00

(52) U.S. Cl. 118/723 R; 118/50; 250/492.3

(57) ABSTRACT

To enable suitable plasma processing with reduced damage to a processing target ascribable to plasma generation. In a plasma processing apparatus including at least: a plasma processing chamber in which plasma processing is applied to a processing target; a processing target supporting means for setting the processing target in the plasma processing chamber; and a plasma generating means for generating a plasma in the plasma processing chamber, the present invention uses the plasma generating means that is capable of supplying intermittent energy.

This is a continuation in part of PCT Application No. PCT/JP2004/007485, filed on May 31, 2004, which claims the benefit of Japanese Patent Application No. 2003-152808, filed on May 29, 2003, all of which are incorporated herein by reference.

### BACKGROUND OF THE INVENTION

The present invention relates to a plasma processing apparatus and a plasma processing method suitably usable for applying various kinds of plasma processing to a processing target in order to manufacture an electronic device and the like.

### DESCRIPTION OF THE RELATED ART

A plasma processing apparatus of the present invention is widely applicable to plasma processing in general, typically, to manufacturing of a semiconductor or materials of electronic devices such as a semiconductor device and a liquid crystal device, but for descriptive convenience, a background art of a semiconductor device will be described here as an example.

Generally, in manufacturing processes of a semiconductor device, various kinds of processing such as CVD (Chemical Vapor Deposition) processing, etching processing, and sputtering processing are applied to a semiconductor device substrate (wafer) being a processing target.

Conventionally, a plasma processing apparatus is often used for such various kinds of processing. This is because the use of the plasma processing apparatus is advantageous in that chemical reaction, which occurred only at high temperature in a conventional art, can be caused at low temperature by using a nonequilibrium low-temperature plasma.

Recent miniaturization of a semiconductor device has given rise to a strong demand for a device with a thinner film structure. For example, in a semiconductor device structure of a MOS type which is the most popular as the structure of the semiconductor device, there has been a high need for an extremely thin (for example, on the order of 2 nm or less) and high-quality gate insulation film according to so-called scaling rule.

Conventionally, the use of a plasma (for example, an inductively coupled plasma (ICP), a microwave plasma, or the like) has been in the mainstream in the formation or processing (oxidation processing, nitridation processing, or the like) of such a gate insulation film.

However, in accordance with the aforesaid trend toward a thinner film structure of the device, there often arise problems of damage that has conventionally been of substantially no significance, in particular, damage to a processing target ascribable to electrons, ions, and/or ultraviolet light generated by the plasma.

The occurrence of such damage to the processing target tends to cause new problems such as poor breakdown voltage of the gate insulation film, increased leakage current, and reduced transistor driving current.

### SUMMARY OF THE INVENTION

It is an object of the present invention to provide a plasma processing apparatus and a plasma processing method overcoming the aforesaid drawbacks of the conventional art.

It is another object of the present invention to provide a plasma processing apparatus and a plasma processing method that realize suitable plasma processing with reduced damage to a processing target ascribable to plasma generation.

As a result of assiduous studies, the present inventor has found out that it is remarkably effective for achieving the objects stated above that a processing target is given a plasma generated based on energy that is supplied intermittently (namely, at predetermined intervals), instead of a plasma generated based on energy that is supplied continuously (or using a continuous wave) as in the conventional art.

The above findings are the basis of the plasma processing apparatus of the present invention, and to be in more detail, the plasma processing apparatus of the present invention is a plasma processing apparatus including at least: a plasma processing chamber in which plasma processing is applied to a processing target; a processing target supporting means for setting the processing target in the plasma processing chamber; and a plasma generating means for generating a plasma in the plasma processing chamber, wherein the plasma generating means is capable of generating the plasma based on intermittent energy supply.

Further, a plasma processing method of the present invention is a method of applying plasma processing to a processing target by using a plasma processing apparatus including at least: a plasma processing chamber in which the plasma processing is applied to the processing target; a processing target supporting means for setting the processing target in the plasma processing chamber; and a plasma generating means for generating a plasma in the plasma processing chamber, wherein the plasma is generated based on intermittent energy supply while the processing target supporting means supports the processing target, thereby applying the plasma processing to the processing target.

In the present invention having the above-described structure, a radical efficiently generated by the plasma generation based on the intermittently supplied energy (a microwave, RF, or the like) from the plasma generating means is supplied to the processing target, so that it is possible to substantially reduce electron temperature of the plasma processing, with substantially no deterioration in efficiency of the plasma processing.

In addition, in the present invention, because of reduced ion bombardment and reduced charge-up damage, it is also possible to substantially reduce damage to the processing target ascribable to ions and/or ultraviolet light from the plasma generated based on the intermittent energy supply. Therefore, according to the present invention, it is possible to perform predetermined plasma processing (for example, plasma nitridation and/or plasma oxidation processing), with substantially no deterioration in efficiency of the plasma processing.

On the other hand, in conventional plasma processing, even when a plasma with relatively low electron temperature (for example, ECR plasma or the like) is used, the electron temperature of the plasma is about 2 eV to 4 eV, and therefore, giving a plasma generated based on continuous energy supply to a processing target involves a high possibility of causing damage to the processing target. Therefore, according to the present invention, it is possible to reduce the damage to the processing target compared with the conventional art.

As described above, according to the present invention, it is possible to provide a plasma processing apparatus and a plasma processing method that realize suitable plasma processing with reduced damage to a processing target ascribable to plasma generation. Therefore, applying the present invention to, for example, film formation processing of an insulation film makes it possible to prevent the occurrence of problems ascribable to the damage, such as poor breakdown voltage of the insulation film, increased leakage current, and reduced transistor driving current.

### BRIEF DESCRIPTION OF THE DRAWINGS

FIG. 1 is a schematic cross-sectional view showing one preferred embodiment of a plasma processing apparatus of the present invention;

FIG. 2 is a schematic cross-sectional view showing an example of a detailed configuration of the plasma processing apparatus shown in FIG. 1;

FIG. 3 is a graph showing electron temperature in a wafer from its center to edge, when plasma processing is applied under 1000 W power by continuous energy supply based on a continuous wave and by intermittent energy supply based on a pulse;

FIG. 4 is a graph showing electron density in a wafer from its center to edge, when plasma processing is applied under 1000 W power by continuous energy supply based on a continuous wave and by intermittent energy supply based on a pulse;

FIG. 5 is a graph showing electron temperature in a wafer from its center to edge, when plasma processing is applied under 1500 W power by continuous energy supply based on a continuous wave and by intermittent energy supply based on a pulse

FIG. 6 is a graph showing electron density in a wafer from its center to edge, when plasma processing is applied under 1500 W power by continuous energy supply based on a continuous wave and by intermittent energy supply based on a pulse;

FIG. 7 is a graph showing electron temperature in a wafer from its center to edge, when plasma processing is applied under 2000 W power by continuous energy supply based on a continuous wave and by intermittent energy supply based on a pulse;

FIG. 8 is a graph showing electron density in a wafer from its center to edge, when plasma processing is applied under 2000 W power by continuous energy supply based on a continuous wave and by intermittent energy supply based on a pulse;

FIG. 9 is a graph showing the correlation between a duty ratio of the pulse and electron temperature; and

FIG. 10 is a graph showing the correlation between a duty ratio of the pulse and electron density.

### DETAILED DESCRIPTION OF THE INVENTION

Hereinafter, the present invention will be more concretely described, with reference to the drawings when necessary. In the description below, “part” and “%” representing a quantity ratio are on a mass basis unless otherwise noted.

(Plasma Processing Apparatus)

A plasma processing apparatus of the present invention includes at least: a plasma processing chamber in which plasma processing is applied to a processing target; a processing target supporting means for setting the processing target in the plasma processing chamber; and a plasma generating means for generating a plasma in the plasma processing chamber. In this plasma processing apparatus, the plasma generating means is capable of generating the plasma based on intermittent energy supply.

(Intermittent Energy Supply)

In the present invention, the “intermittent energy supply” means that an instant at which energy supply for plasma generation becomes zero takes place at least once in a predetermined time range (for example, 1 millisecond). In the present invention, as long as the “intermittent energy supply” takes place, a form of “intermittent” is not limited to a specific form. That is, a waveform for the energy supply may be any of well-known waveforms such as a rectangular waveform, a triangular waveform, and a curved waveform (for example, a sine curve). The “intermittent energy supply” preferably takes place based on the combination of a rectangular wave and a high-frequency wave.

In the present invention, in view of balancing between plasma generation efficiency and reduction in damage to the processing target, the total time in which the energy supply for plasma generation becomes zero is preferably 20μ to 200μ seconds, and more preferably, 50μ to 100μ seconds, in a 1000 millisecond period.

(Modulation)

In the present invention, the aforesaid “intermittent energy supply” may be given in a time-modulation manner when necessary.

(One Embodiment of the Plasma Processing Apparatus)

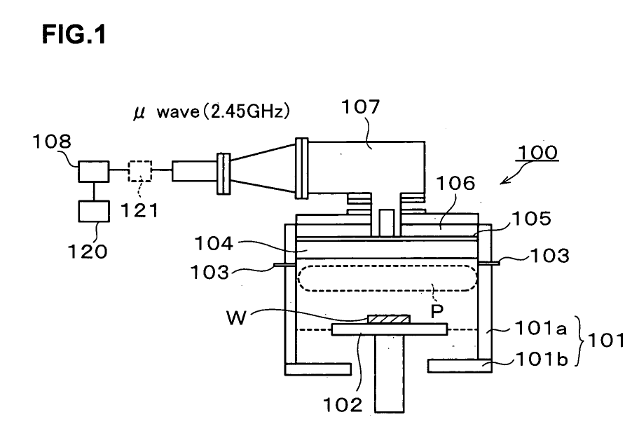

FIG. 1 is a schematic cross-sectional view showing another example of the plasma processing apparatus according to the present invention. This embodiment will describe a case where the plasma processing apparatus is applied to plasma CVD (Chemical Vapor Deposition) processing. When the apparatus of the embodiment shown in FIG. 1 is used for other plasma processing (for example, plasma oxidation and/or plasma nitridation processing), for example, process gas such as oxygen-containing gas or nitrogen-containing gas is supplied from a later-described process gas supply nozzle 103. Incidentally, in the embodiment shown in FIG. 1, a planar antenna member 105 is used as an antenna member.

As shown in FIG. 1, this plasma processing apparatus 100 has a plasma processing chamber 101 in a cylindrical shape as a whole, with a sidewall 101a and a bottom portion 101b thereof, for example, being made of conductors such as aluminum, and an inner part of the plasma processing chamber 101 is formed as an airtight processing space S.

This plasma processing chamber 101 houses a mounting table 102 for placing a processing target (for example, a semiconductor wafer W) on an upper surface thereof. This mounting table 102 is made of, for example, anodized aluminum or the like and formed in a substantially columnar shape that is protruding and flat.

On the upper surface of the aforesaid mounting table 102, an electrostatic chuck or a clamping mechanism (not shown) for keeping the wafer W supported on the upper surface is provided. Further, the mounting table 102 is connected to a matching box (not shown) and a high-frequency power source for bias (for example, for 13.56 MHz; not shown) via a feeder (not shown). Note that in a case of CVD (that is, when the bias is not applied), this high-frequency power source for bias need not be provided.

Meanwhile, in the sidewall of the aforesaid plasma processing chamber 101, the gas supply nozzle 103 for introducing aforesaid vapor-containing gas or other gas into a vessel is provided as a gas supply means.

A ceiling portion of the plasma processing chamber 101 has an opening, in which an insulating plate 104 (for example, about 20 mm in thickness) made of, for example, quartz or a ceramic material such as Al₂O₃ and transmissive for a microwave is airtightly provided via a sealing member (not shown) such as an O-ring.

On an upper surface of this insulating plate 104, the disk-shaped planar antenna member 105 and a retardation member 106 (made of quartz, Al₂O₃, AiN, or the like) having a high dielectric-constant property are provided. A microwave propagates to the planar antenna member 105 from a coaxial waveguide 107. The frequency of the microwave is not limited to 2.45 GHz but other frequency, for example, 8.35 GHz may be used.

The microwave is generated by, for example, a microwave generator 108. The microwave generator 108 intermittently outputs the microwave, for example, in a pulsed manner, under the control by a controller 120 controlling, for example, ON-OFF thereof, and supplies the microwave to the waveguide 107. Incidentally, instead of such ON-OFF control, a modulator 121 may time-modulates the microwave from the microwave generator 108 to intermittently supply energy of the microwave to the waveguide 107.

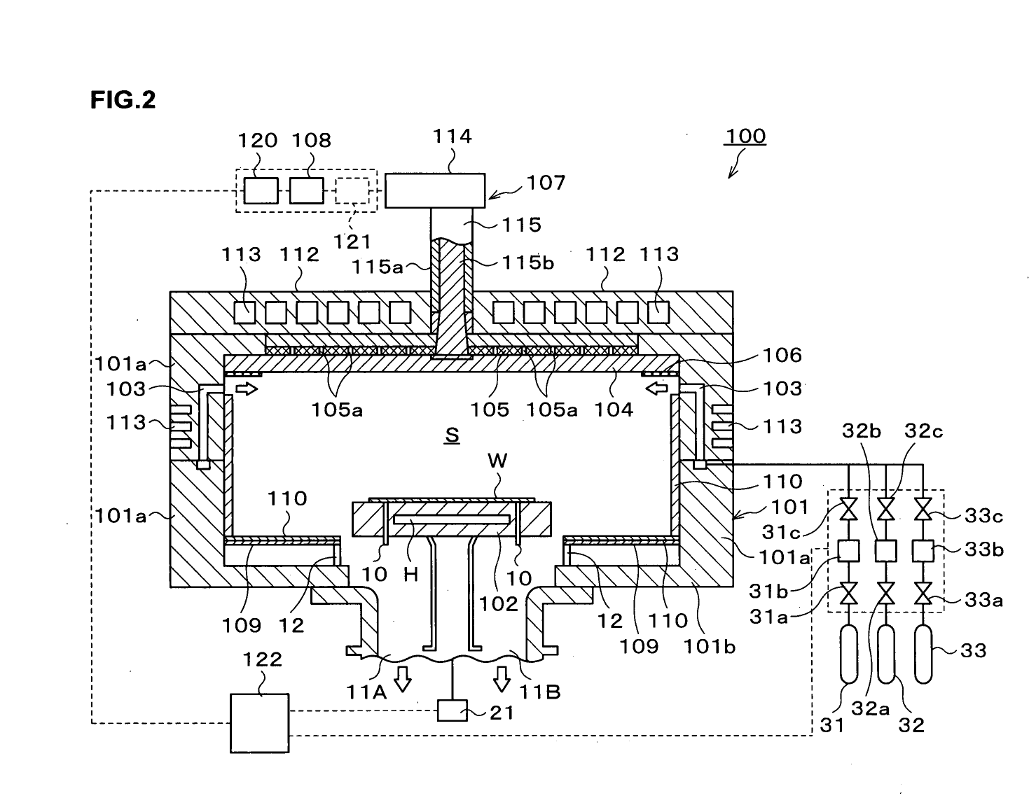

FIG. 2 is a schematic cross-sectional view showing a more detailed example of the configuration shown in FIG. 1. As shown in FIG. 2, this plasma processing apparatus 100 has the plasma processing chamber 101 in a cylindrical shape as a whole, with the sidewall 101a and the bottom portion 101b thereof, for example, being made of conductors such as aluminum, and the inner part of the plasma processing chamber 101 is formed as the airtight processing space S.

This plasma processing chamber 101 houses the mounting table (stage) 102 for placing a processing target (for example, a semiconductor wafer W) on the upper surface thereof. This mounting table 102 has therein a heater H for heating the wafer W when necessary. The mounting table 102 further has lift pins 10 for lifting the wafer W.

Meanwhile, in the sidewall 101a of the aforesaid plasma processing chamber 101, the gas supply nozzle 103 as a gas supply port for introducing rare gas such as Ar and Kr, and oxygen gas such as O₂, nitrogen gas such as N₂, or vapor-containing gas into the aforesaid vessel is provided. In FIG. 2, for the purpose of uniform gas exhaust, a gas baffle plate 109 is disposed to be substantially perpendicular to the sidewall 101a, to allow uniform exhaust of the inside of the processing space S. The gas baffle plate 109 is supported by a supporting member 12. Further, on inner sides (sides facing the processing space S) of the sidewall 101a and the gas baffle plate 109, liners 110 made of, for example, quartz glass are disposed for preventing the occurrence of particles such as metal contamination generated from the walls due to the sputtering by ions.

In the opening of the ceiling portion of the plasma processing chamber 101, the insulating plate (dielectric) 104 (for example, about 20 mm in thickness) made of, for example, quartz or a ceramic material such as Al₂O₃ and transmissive for a microwave is airtightly provided via the sealing member (not shown) such as an O-ring.

On the upper surface of this insulating plate 104, the disk-shaped planar antenna member 105 and the retardation member 106 (for example, made of quartz, Al₂O₃, AiN, or the like) having a high dielectric-constant property and covering the planar antenna member 105 are provided. The planar antenna member 105 is constituted of a thin disk made of a conductive material, for example, silver- or gold-plated such as copper or aluminum. The planar antenna member 105 may be in a square shape or a polygonal shape, not limited to the disk shape. As the planar antenna member 105, used is a RLSA (Radial Line Slot Antenna) having a plurality of pairs of slots 105a, the slots in each pair making a T shape or diagonally facing each other, and these pairs being arranged for example, concentrically, circularly or spirally. Further, owing to a wavelength shortening effect of the retardation member 106 having the high dielectric-constant property, the guide wavelength of the microwave can be shortened.

In FIG. 2, a conductive shield cover is disposed on the retardation member 106 to cover the planar antenna member 105, the retardation member 106, and so on. A cooling plate 112 for cooling the planar antenna member 105, the retardation member 106, and so on is disposed on the shield cover, and refrigerant paths 113 for cooling these members are provided inside the cooling plate 112 and the sidewall 101a in order to prevent thermal deformation and breakage of the planar antenna member 105, the retardation member 106, and the insulating plate 104 for stable plasma generation. The microwave (with the frequency of 2.45 GHz or the like) propagates to the aforesaid planar antenna member 105 from the waveguide 107, as described above. The waveguide 107 has a rectangular waveguide 114 and a coaxial waveguide 115, and the coaxial waveguide 115 is composed of an outer conductor 115a and an inner conductor 115b. The microwave generated by the microwave generator 108 is uniformly propagated to the planar antenna member 105 via the rectangular waveguide 114 and the coaxial waveguide 115 and is further supplied uniformly from the planar antenna member 105 via the insulating plate 104.

Gas in the atmosphere in the plasma processing chamber 101 is uniformly exhausted by an exhaust device 21 via exhaust ports 11A, 11B.

As gas supply sources to the aforesaid gas nozzle 103 being the gas supply means, an inert gas supply source 31, a process gas supply source 32, and a process gas supply source 33 are prepared, and these gas supply sources are connected to the gas nozzle 103 via inner opening/closing valves 31a, 32a, 33a, massflow controllers 31b, 32b, 33b, and outer opening/closing valves 31c, 32c, 33c, respectively. Flow rates of the gases supplied from the gas nozzle 103 are controlled by the massflow controllers 31b, 32b, 33b.

A controller 122 controls the ON-OFF and output control of the aforesaid microwave generator 108, the flow rate adjustment by the massflow controllers 31b, 32b, 33b, adjustment of an exhaust amount of the exhaust device 21, the heater H of the mounting table 102, the controller 120, and so on so as to allow the plasma processing apparatus 100 to perform the optimum processing.

Next, an example of a processing method using the plasma processing apparatus 100 as structured above will be described.

Referring to FIG. 2, first, a carrier arm (not shown) sets a semiconductor wafer W in the plasma processing chamber 101 via a not-shown gate valve 68, and the lift pins 10 are moved up/down to place the wafer W on the upper surface of the mounting table 102. With a process pressure inside the plasma processing chamber 10 being kept at a predetermined value, for example, within a range from 0.01 Pa to several Pa, argon gas, for instance, is supplied from a plasma gas supply nozzle (not shown) at a controlled flow rate, and at the same time, deposition gas such as, for example, SiH₄, O₂, or N₂ is supplied from the process gas supply nozzle 103 at a controlled flow rate. At the same time, the microwave from the microwave generator 108 is intermittently supplied to the planar antenna member 105 via the coaxial waveguide 107, and the microwave whose wavelength is shortened by the retardation member 106 is introduced into the processing space S to generate a plasma, whereby predetermined plasma processing, for example, film deposition processing by plasma CVD is performed.

(Structures of the Respective Parts)

The structures of the respective parts shown in FIG. 1 and FIG. 2, materials usable in the apparatus shown in FIG. 1 and FIG. 2, and so on will be described.

(Substrate for an Electronic Device)

The aforesaid substrate for an electronic device usable in the present invention is not limited to a specific one, but one kind or the combination of two kinds or more among well-known substrates for electronic devices can be appropriately selected for use. Examples of such substrates for electronic devices are a semiconductor material, a liquid crystal device material, and so on. Examples of the semiconductor material are a material mainly made of single-crystal silicon and a material mainly made of silicon germanium, and examples of the liquid crystal device material are polysilicon, amorphous silicon, and so on deposited on a glass substrate.

(Process Gas)

Process gas usable in the present invention is not limited to specific one. That is, in oxidation processing of the electronic device substrate in the present invention, at least oxygen gas or gas containing oxygen atoms is usable as the process gas without any special limitation. In nitridation processing of the electronic device substrate in the present invention, at least nitrogen gas or gas containing nitrogen atoms such as NH₃ is usable as the process gas without any special limitation. Moreover, in the CVD processing in the present invention, deposition gas, for example, Si-containing gas such as TMS or TEOS, or C-containing gas is usable without any special limitation. Further, fluorocarbon-based etching gas such as CF₄, C₄F₈, or C₅F₆ is also usable.

(Examples of Suitable Process Gas)

Examples of the process gas suitably usable in the present invention and flow rates thereof will be shown below.
(1) In the case of oxidation processing

Ar/O₂=1000/10 sccm to 1000/100 sccm
(2) In the case of nitridation processing

Ar/N₂=1000/10 sccm to 1000/200 sccm
(3) In the case of CVD

Ar/C₄F₈=1000/20 sccm to 1000/400 sccm

(Rare Gas)

Rare gas usable for plasma generation in the present invention is not limited to specific one, but one kind or the combination of two kinds or more among well-know rare gases usable in electronic device manufacture can be appropriately selected for use. Example of such process gas are krypton (Kr), xenon (Xe), helium (He), and argon (Ar).

(Conditions of Process Gas)

In forming an oxynitride film by the present invention, the following conditions are suitably adopted in view of characteristics of a film to be formed.
(1) Flow rate of the rare gas (for example, Kr, Ar, He, or Xe): 200 sccm to 1000 sccm, more preferably, 500 sccm to 1000 sccm
(2) Flow rate of the process gas: 10 sccm to 100 sccm, more preferably, 20 sccm to 50 sccm
(3) Temperature: room temperature (25° C.) to 500° C., more preferably, 250° C. to 400° C.
(4) Pressure in the process chamber: 5 Pa to 300 Pa, more preferably, 6 Pa to 150 Pa
(5) Microwave: 0.5 W/cm² to 3 W/cm², more preferably, 0.7 W/cm² to 1.5 W/cm² (ON/OFF of the microwave is preferably 10 KHz to 100 KHz, and a duty ratio is preferably 20% to 80%).

(Suitable Plasma)

Characteristics of the plasma suitably usable in the present invention are as follows.
(1) Electron temperature: 0.5 eV to 1.0 eV
(2) Density: 1 to 20×10¹¹/cm³
(3) Uniformity of plasma density: ±10%

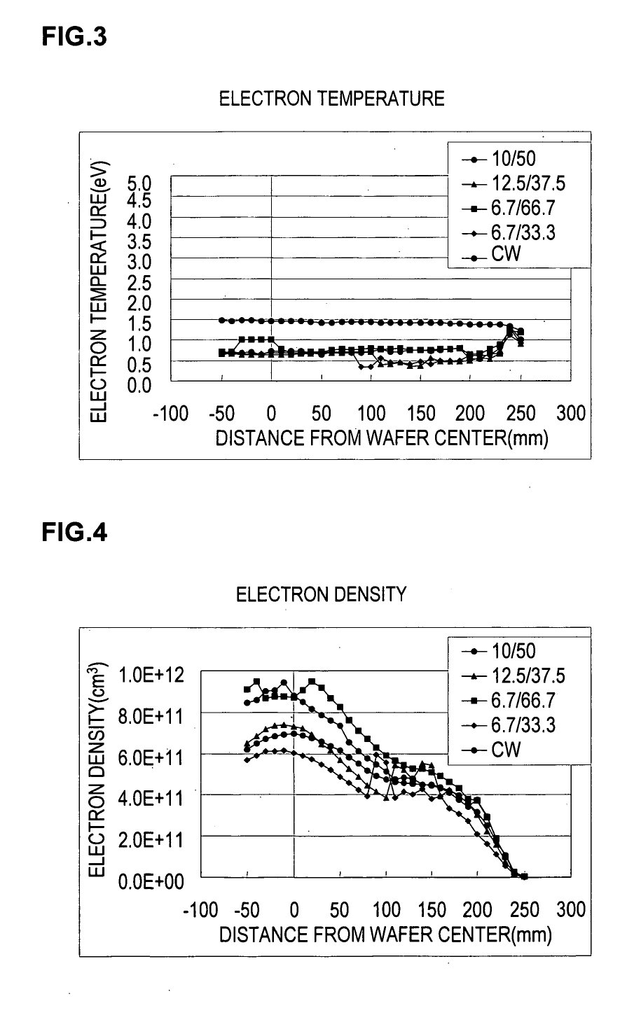

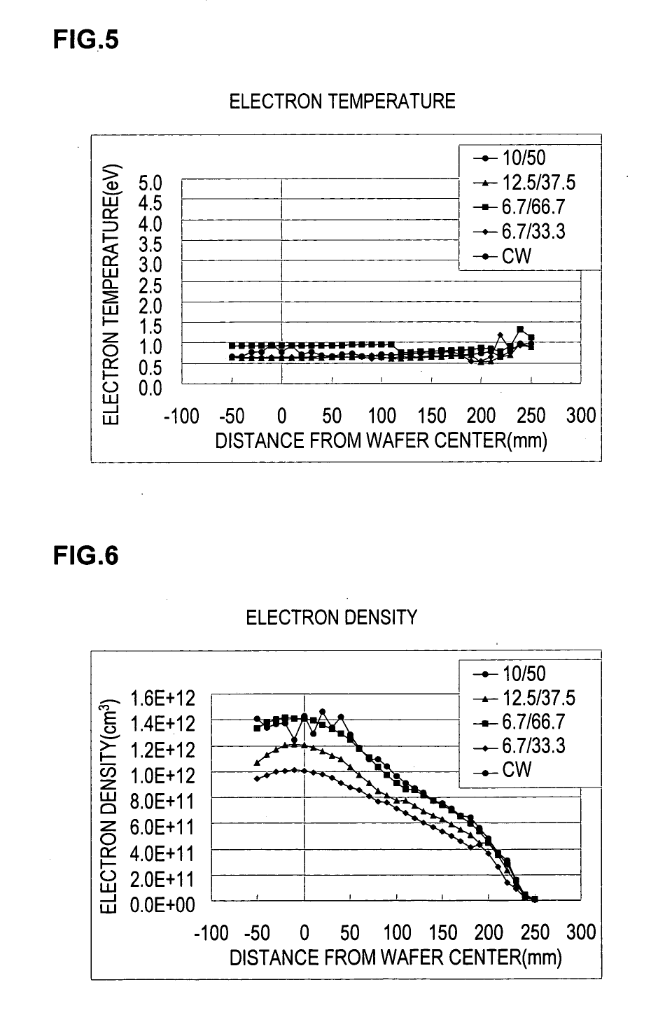

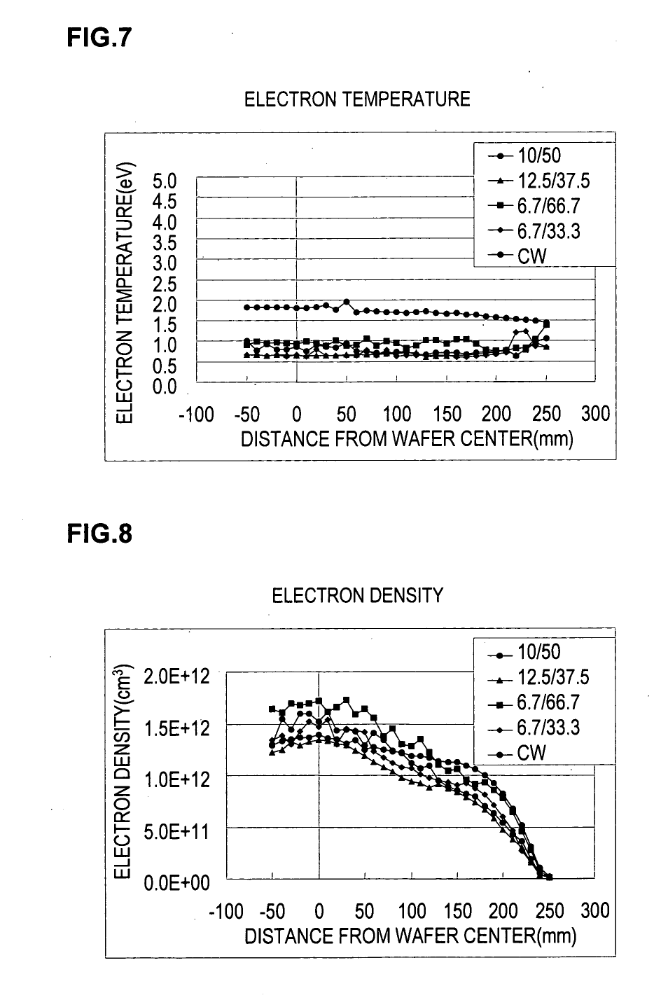

FIG. 3 to FIG. 8 show results of the electron temperature (FIG. 3, FIG. 5, FIG. 7) and the electron density (FIG. 4, FIG. 6, FIG. 8) in a wafer from its center to edge, when plasma processing is applied by continuous energy supply based on a continuous wave (CW) and by intermittent energy supply based on a pulse. Conditions and so on for these data are shown in the drawings. The conditions in all the processing in FIG. 3 to FIG. 8 were set such that flow rate of Ar/N₂: 1000/40 sccm and pressure in the process chamber: 50 mTorr, with varied plasma powers of 1000 W (FIG. 3, FIG. 4), 1500 W (FIG. 5, FIG. 6), and 2000 W (FIG. 7, FIG. 8). In each of the cases, the frequency/duty ratio of the pulse was set in four different ways for study, namely, 10 [kHz]/50[%], 12.5 (kHz)/37.5[%], 6.7 [kHz]/66.7%, and 6.7 [kHz]/33.3[%].

As for the electron temperature (Te), the following result was obtained. Note that each of the following values is an average value of the electron temperature in a region within a 250 mm radius from the center of the wafer W (average value in a region in the wafer).
(1) The electron temperature for each frequency/duty ratio of the pulse when the plasma power is 1000 W is as follows.
In the case of 12.5 [kHz]/37.5[%], the average value is 0.56 [eV].
In the case of 10 [kHz]/50[%], the average value is 0.70 [eV].
In the case of 6.7 [kHz]/66.7[%], the average value is 0.75 [eV].
In the case of 6.7 [kHz]/33.3[%], the average value is 0.57 [eV].
(2) The electron temperature for each frequency/duty ratio of the pulse when the plasma power is 1500 W is as follows.
In the case of 12.5 [kHz]/37.5[%], the average value is 0.65 [eV].
In the case of 10 [kHz]/50[%], the average value is 0.74 [eV].
In the case of 6.7 [kHz]/66.7[%], the average value is 0.86 [eV].
In the case of 6.7 [kHz]/33.3[%], the average value is 0.63 [eV].
(3) The electron temperature for each frequency/duty ratio of the pulse when the plasma power is 2000 W is as follows.
In the case of 12.5 [kHz]/37.5[%], the average value is 0.69 [eV].
In the case of 10 [kHz]/50[%], the average value is 0.75 [eV].
In the case of 6.7 [kHz]/66.7[%], the average value is 0.91 [eV].
In the case of 6.7 [kHz]/33.3[%], the average value is 0.66 [eV].

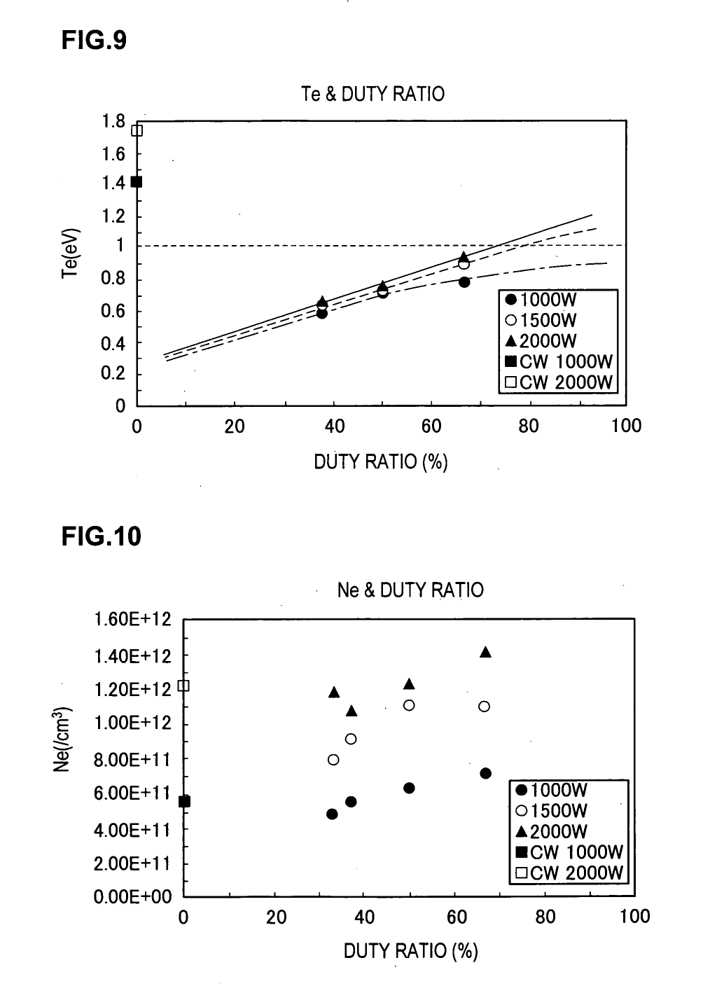

Next, FIG. 9 and FIG. 10 show the results of studies on the electron temperature (Te) and the electron density (Ne) vs. the duty ratio of the pulse when the plasma nitridation processing was applied by a plasma generated by intermittent energy supply based on the pulse. These studies were conducted under the same conditions as above, namely, flow rate of Ar/N₂: 1000/40 sccm and pressure in the process chamber: 50 mTorr, with varied plasma powers of 1000 W, 1500 W, and 2000 W. Each electron temperature shown in FIG. 9 and each electron density shown in FIG. 10 are both average values in a region within a 150 mm radius from the center of the wafer W. For comparison, also shown are electron temperature (Te) and electron density (Ne) when the continuous wave (CW: 1000 W and 2000 W) is used

It is seen from these results that a preferable range of the duty ratio of the pulse for generating a plasma whose electron temperature is 1 eV or lower is 1% to 80% when the power is 1500 W and 2000 W, and 1% to 99% when the power is 1000 W.

As is apparent from the above-described results, the electron temperature can be made lower in the processing by the plasma generated based the intermittent energy supply according to the present invention than in the processing by the plasma generated based on the continuous energy supply using the continuous wave. In addition, as for the electron density, the generated plasma has electron density of 1 to 20×10¹¹/cm³, which is on the same level or higher than that in the case of the continuous wave, and as for the electron temperature, the generated plasma has low electron temperature, namely, 0.5 eV to 1 eV. As described above, the duty ratio is preferably 1% to 99%, more preferably, 1% to 80%. When the electron temperature (Te) is lower than 0.8 eV, the duty ratio is more preferably, 1% to 60%, still more preferably, 30% to 50%. Therefore, it is possible to realize uniform and high-quality plasma processing with reduced damage to the processing target.

(Other Plasma)

In the above-described embodiment, the plasma generation using the microwave is described, but the plasma generating means (plasma source) is not limited to a specific one as long as the energy is intermittently supplied. That is, besides the microwave plasma, ICP (inductively coupled plasma), plasmas of ECR, a surface reflected wave, magnetron, and the like are also usable.

(Other Application)

In the above-described embodiment, the case where the film deposition processing is applied to the semiconductor wafer is described as an example, but this is not restrictive, and the present invention is also applicable to other plasma processing such as plasma etching processing and plasma ashing processing. Further, the processing target is not limited to the semiconductor wafer, but the present invention is applicable to a glass substrate, a LCD (liquid crystal device) substrate, and the like.

The present invention is useful for plasma processing such as, for example, etching processing, ashing processing, and film deposition processing in manufacturing processes of substrates for a semiconductor device and a flat display.

What is claimed is:

1. A plasma processing apparatus comprising at least: a plasma processing chamber in which plasma nitridation and/or plasma oxidation processing are/is applied to a processing target; a processing target supporting means for setting the processing target in said plasma processing chamber; and a plasma generating means for generating a plasma in said plasma processing chamber,
wherein said plasma generating means generates the plasma having electron temperature of 0.5 eV to 1 eV in said plasma processing chamber based on intermittent energy supply.

2. The plasma processing apparatus according to claim 1,
wherein the intermittent energy supply is given in a pulsed manner.

3. The plasma processing apparatus according to claim 1,
wherein the intermittent energy supply is given in a time-modulation manner.

4. The plasma processing apparatus according to claim 1,
wherein the intermittent energy supply is given by modulation of a pulse width, a pulse space, and/or a pulse position.

5. The plasma processing apparatus according to claim 4,
wherein the energy is supplied from an antenna member including a planar antenna (RLSA) having a plurality of slots.

6. The plasma processing apparatus according to claim 1,
wherein electron density of the intermittent plasma is 1 to 20×10¹¹/cm³.

7. A plasma processing method for applying plasma processing to a processing target,
the method using a plasma processing apparatus comprising at least:
a plasma processing chamber in which the plasma processing is applied to the processing target;
a processing target supporting means for setting the processing target in the plasma processing chamber; and
a plasma generating means for generating a plasma in the plasma processing chamber, and
wherein the plasma having electron temperature of 0.5 eV to 1 eV is generated based on intermittent energy supply by the plasma generating means and the plasma processing is applied to the plasma processing target by the plasma.

8. The plasma processing method according to claim 7,
wherein electron density of the intermittent plasma is 1 to 20×10¹¹/cm³.

9. The plasma processing method according to claim 7,
wherein in said plasma processing, rare gas and gas containing a nitrogen atom are supplied into the plasma processing chamber, the plasma having the electron temperature of 0.5 eV to 1 eV is generated by the intermittent energy supply, and nitridation processing is applied to the processing target by the plasma containing the rare gas and the nitrogen atom.

10. The plasma processing method according to claim 9,
wherein the rare gas is argon gas and the gas containing the nitrogen atom is nitrogen gas, and a flow rate ratio of the argon gas and the nitrogen gas is 5 to 100:1.

11. The plasma processing method according to claim 7,
wherein in said plasma processing, rare gas and gas containing an oxygen atom are supplied into the plasma processing chamber, the plasma having the electron temperature of 0.5 eV to 1 eV is generated by the intermittent energy supply, and oxidation processing is applied to the processing target by the plasma containing the rare gas and the oxygen atom.

12. The plasma processing method according to claim 11,
wherein the rare gas is argon gas and the gas containing the oxygen atom is oxygen gas, and a flow rate ratio of the argon gas and the oxygen gas is 10 to 100:1.

13. The plasma processing method according to claim 9,
wherein the rare gas is one gas out of Ar, Kr, He, and Xe.

14. The plasma processing method according to claim 11,
wherein the rare gas is one gas out of Ar, Kr, He, and Xe.

15. A plasma processing method for applying plasma processing to a processing target,
the method using a plasma processing apparatus comprising at least:
a plasma processing chamber in which the plasma processing is applied to the processing target;
a processing target supporting means for setting the processing target in the plasma processing chamber; and
a plasma generating means for generating a plasma in the plasma processing chamber, and
wherein the plasma having electron temperature of 0.5 eV to 1 eV is generated by intermittent energy supply by the plasma generating means, and nitridation processing is applied to the processing target by the plasma to form an oxynitride film.

16. The plasma processing apparatus according to claim 1,
wherein the processing target is a semiconductor material made of a material whose main component is single-crystal silicon or a material whose main component is silicon germanium.

17. The plasma processing apparatus according to claim 1,
wherein the processing target is a semiconductor material made of a liquid crystal device material such as polysilicon or amorphous silicon.

18. The plasma processing method according to claim 7,
wherein the processing target is a semiconductor material made of a material whose main component is single-crystal silicon or a material whose main component is silicon germanium.

19. The plasma processing method according to claim 7,
wherein the processing target is a semiconductor material made of a liquid crystal device material such as polysilicon or amorphous silicon.

20. The plasma processing method according to claim 7,
wherein the plasma processing is CVD processing or etching processing.

21. A plasma processing apparatus applying plasma processing to a processing target by supplying intermittent energy into a processing vessel and generating a plasma, the apparatus comprising:
a mounting table setting the processing target in a processing space formed in the processing vessel;
a gas supply means for introducing process gas to the processing vessel;
an insulating member airtightly covering an opening formed in an upper part of the processing vessel;
an antenna member disposed on an upper surface of said insulating member to generate the plasma in the processing vessel;
an energy generator connected to said antenna member to supply the energy;
a controller connected to said energy generator to control ON-OFF for the intermittent supply of the energy; and
an exhaust device exhausting an inside of the processing vessel,
wherein said energy generator is made ON-OFF by said controller to intermittently supply the energy into the processing vessel via said antenna member and said insulating member, thereby generating the plasma having electron temperature of 0.5 eV to 1 eV.

22. The plasma processing apparatus according to claim 21,
wherein said insulating member is made of a quartz or ceramic material.

23. The plasma processing apparatus according to claim 21,
wherein said antenna member is a planar antenna member.

24. The plasma processing apparatus according to claim 21,
wherein said mounting table has an electrostatic chuck or a clamping mechanism.

25. The plasma processing apparatus according to claim 21,
wherein a bias power source is connected to said mounting table.

26. The plasma processing apparatus according to claim 21,
wherein a heater is provided in said mounting table.

27. The plasma processing apparatus according to claim 15,
wherein the processing vessel is set to a pressure of 5 Pa to 300 Pa and is set to a process temperature of room temperature to 500° C., and a pulse of the intermittently supplied energy is controlled so as to have a pulse frequency within a range of 10 kHz to 100 kHz and a duty ratio within a range of 20% to 80%.

28. The plasma processing apparatus according to claim 1,
wherein the generated plasma has electron temperature of 0.5 eV to 0.75 eV when a duty ratio at the time of the intermittent energy supply is within a range of 30% to 60%.

29. The plasma processing method according to claim 7,
wherein the generated plasma has electron temperature of 0.5 eV to 0.75 eV when a duty ratio at the time of the intermittent energy supply is within a range of 30% to 60%.

30. A plasma processing apparatus comprising: a plasma processing chamber in which plasma processing is applied to a processing target; and a plasma generating means for generating a plasma in said plasma processing chamber,
wherein said plasma generating means has a planar antenna member, and
wherein said plasma generating means generates the plasma in said plasma processing chamber based on intermittent energy supply.
